(19) United States
(12) Patent Application Publication
(10) Pub. No.: US 2026/0161836 A1
(43) Pub. Date: Jun. 11, 2026

(54) DESIGN SUPPORT SYSTEM AND DESIGN SUPPORT METHOD

(71) Applicant: NOHARA GROUP, INC., Tokyo (JP)

(72) Inventor: Wataru ISHIDA, Tokyo (JP)

(21) Appl. No.: 18/707,495

(22) PCT Filed: Nov. 17, 2022
(86) PCT No.: PCT/JP2022/042738

§ 371 Date: May 3, 2024

(30) Foreign Application Priority Data
Nov. 29, 2021 (JP) 2021-193187

(51) Int. Cl. G06F 30/13

(52) U.S. Cl. CPC G06F 30/13

(57) ABSTRACT

A design support system includes: a part providing unit for providing a BIM part including a basic parameter for representing a three-dimensional shape of the BIM part in a BIM model of a construction object and code information, in such a manner that the BIM part is capable of being incorporated into the BIM model; a storage unit for storing an additional parameter for creating a drawing regarding construction or manufacturing of the BIM part, in association with the code information of the BIM part; a parameter acquiring unit for acquiring the code information of the BIM part that is included in the BIM model, and for acquiring the additional parameter in association with the acquired code information from the storage unit; and a drawing creating unit for creating the drawing of the BIM part based on the additional parameter acquired by the parameter acquiring unit.

### TECHNICAL FIELD

The present disclosure relates to a design support system and a design support method.

### BACKGROUND ART

BIM (or Building Information Modeling) has been known as a digital model for being used for construction. A BIM part(s) relating to equipment or the like of a construction object is incorporated in a BIM model of a three-dimensional construction which is created on a computer (see Patent Document 1).

### CITATION LIST

### Patent Literature

[Patent Literature 1] Japanese Unexamined Patent Application Publication No. 2021-5264

### SUMMARY OF INVENTION

### Problem to be Solved by the Invention

As described in the Patent Document 1, various types of attribute information may be embedded in a BIM part. However, if too much information is embedded in the BIM part, the data volume of each BIM part becomes large, and thereby requiring the BIM model to have large storage resources. On the other hand, if information to be embedded into the BIM part is limited to a minimum, it may pose a risk of impairing the merit of the efficiency of the construction process which may be obtained by using information embedded in the BIM part. In other words, the user convenience using the BIM model may be impaired.

In view of the above, one aspect of the present disclosure aims to provide a design support system and a design support method which are capable of improving the user convenience while suppressing an increase in data volume of a BIM model.

### Solution to Problem

A design support system according to one aspect of the present disclosure is configured to includes: a part providing unit for providing a BIM part(s) relating to equipment of a construction object in such a manner that the BIM part is capable of being incorporated into a BIM model of the construction object, wherein the each BIM part includes a basic parameter(s) for representing a three-dimensional shape of the BIM part in the BIM model of the construction object and includes code information that is uniquely assigned to the BIM part; a storage unit for storing an additional parameter(s) for creating a drawing (or figure or the like) regarding construction or manufacturing of the BIM part, in association with the code information of the BIM part; a parameter acquiring unit for acquiring the code information of the BIM part that is included in the BIM model created by a first user, and for acquiring the additional parameter in association with the acquired code information from the storage unit; and a drawing creating unit for creating the drawing of the BIM part based on the additional parameter acquired by the parameter acquiring unit.

According to another aspect of the present disclosure, a design support method is provided. The design support method includes: a step for providing a BIM part(s) relating to equipment of a construction object in such a manner that the BIM part is capable of being incorporated into a BIM model of the construction object, wherein the each BIM part includes a basic parameter(s) for representing a three-dimensional shape of the BIM part in the BIM model of the construction object and includes code information that is uniquely assigned to the BIM part; a step for acquiring the code information of the BIM part that is included in the BIM model created by a first user, and for acquiring an additional parameter(s) in association with the acquired code information by accessing a storage unit that stores the additional parameter for creating a drawing (or figure or the like) regarding construction or manufacturing of the BIM part, in association with the code information of the BIM part; and a step for creating the drawing of the BIM part based on the acquired additional parameter.

According to the above-mentioned design support system and the design support method, code information is embedded in the BIM part itself instead of embedding information (or additional parameters) for creating a drawing. The additional parameter(s) contains a great deal of information. Therefore, by storing such information in the storage unit external to the BIM part instead of in the BIM part, it becomes possible to suppress an increase in the data volume of the individual BIM part. Consequently, it is possible to suppress an increase in the data volume of the BIM model. In addition, the above-mentioned design support system and the design support method are configured such that the parameter acquiring unit acquires additional parameter(s) in association with the code information embedded in the BIM part, and the drawing creating unit creates a drawing according to the additional parameter(s). With such a configuration, the drawing creation process of the BIM part is capable of being automated and facilitated so that it is possible to effectively improve the convenience of the user.

The design support system may further include a parameter changing unit for executing a changing process for changing at least a part of the additional parameter(s) acquired by the parameter acquiring unit, based on operation content inputted by the first user. The drawing creating unit creates the drawing of the BIM part based on the additional parameter(s) that has been changed by the parameter changing unit.

With such a configuration, the first user is allowed to freely customize additional parameters which are previously related to the BIM part. As a result, the content of the drawing relating to the BIM part is able to be flexibly adjusted so that it is possible to further improve the convenience of the user.

The design support system may further include a drawing presenting unit for presenting the drawing created by the drawing creating unit to a second user different from the first user; and an approval processing unit for receiving an approval operation with regard to the drawing by the second user.

With such a configuration, it is possible to smoothly proceed the process of presenting a created drawing to the second user, and the process of accepting an approval operation of the second user with regard to the drawing. Accordingly, it is possible to further improve the convenience of the user.

The approval processing unit receives an input of a comment with regard to the drawing by the first user or the second user. The approval processing unit associates a comment with the drawing in a case where the comment is inputted, so that the comment is represented to both the first user and the second user.

With such a configuration, it is possible to share the content of the inputted comment(s) between the first user and the second user while enabling the input operation of the comment(s) by the first user or the second user with regard to the drawing. As a result, it is possible to promote a communication between the first user and the second user and thereby to smooth the flow until the drawing is approved by the second user. Accordingly, it is possible to further improve the convenience of the user.

The additional parameter includes a construction drawing parameter(s) necessary for creating a construction drawing(s) of the BIM part, and includes a fabrication drawing parameter necessary for creating a fabrication drawing(s) of the BIM part in addition to the construction drawing parameter(s). The drawing creating unit includes a construction drawing creating unit for creating a construction drawing(s) of the BIM part according to the construction drawing parameter(s), and includes a fabrication drawing creating unit for creating a fabrication drawing(s) according to the fabrication drawing parameter(s). The drawing presenting unit presents the construction drawing created by the construction drawing creating unit to the second user. The approval processing unit receives the approval operation with regard to the construction drawing, by the second user. The fabrication drawing creating unit creates the fabrication drawing based on the fabrication drawing parameter(s) after the approval operation with regard to the construction drawing is received by the approval processing unit.

With such a configuration, it is possible to smoothen the flows of the creation and the approval of the construction drawing as well as of the creation of the fabrication drawing after the construction drawing has been approved. Accordingly, it is possible to further improve the convenience of the user.

### Effects of the Invention

According to the present disclosure, it is possible to provide a design support system and a design support method which are capable of improving the user convenience while suppressing an increase in data volume of a BIM model.

### BRIEF DESCRIPTION OF DRAWINGS

FIG. 1 depicts an example showing a functional configuration of a design support system according to one embodiment.

FIG. 2 depicts an example showing a hardware configuration of a computer constituting the design support system illustrated in FIG. 1.

FIG. 3 depicts an example showing BIM parts and a BIM model.

FIG. 4 depicts an example showing a data structure of a BIM part and also a data structure of information stored in a storage unit for each BIM part.

FIG. 5 depicts an example showing a construction drawing parameter.

FIG. 6 depicts an example showing a fabrication drawing parameter.

FIG. 7 depicts an example showing a construction drawing.

FIG. 8 depicts an example showing a fabrication drawing.

FIG. 9 depicts an example showing a flowchart exemplifying operations of the design support system illustrated in FIG. 1.

### Description of Embodiments

Hereinafter, embodiments of the present disclosure will be described in detail with referring to the figures. In the following descriptions, the same or corresponding elements are denoted by the same reference numerals, and redundant descriptions thereof will be omitted.

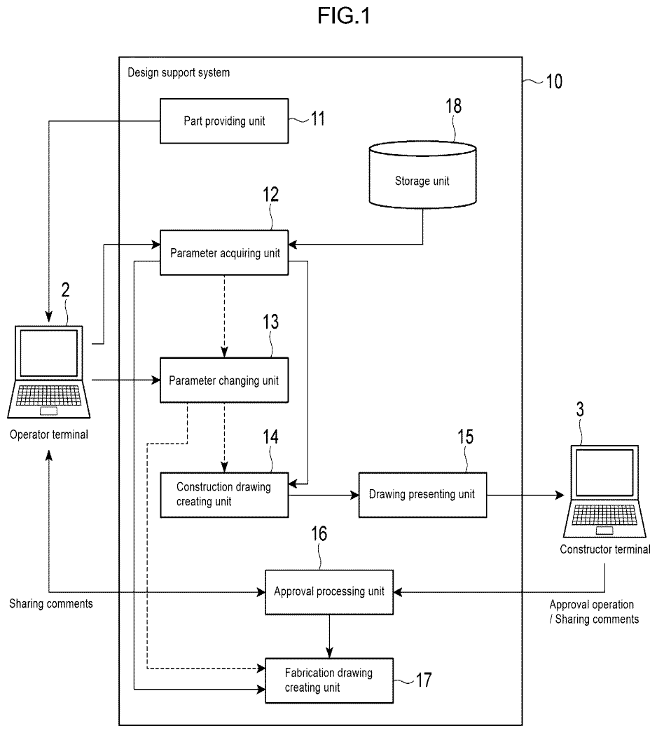

FIG. 1 depicts an example showing a functional configuration of a design support system 10 according to one embodiment. The design support system 10 is a system for supporting to design and create drawings (or figures), using a BIM model of a construction object (or a target to be constructed).

The design support system 10 may be configured by one computer or a plurality of computers such as in the case of the cloud computing. In the latter case, a plurality of computers are connected to each other via a communication network so as to be capable of communicating with each other, thereby functioning as one design support system 10, logically.

The design support system 10 is connected with an operator terminal 2 and a constructor terminal 3 via a communication network, for making communication with them. The communication network may be configured by using a cable or wireless connection. For instance, it is possible to use any one of the Internet, WAN (Wide Area Network), and mobile communication network, as the communication network.

The operator terminal 2 acquires a BIM part(s) from the design support system 10, and creates (or edits) a BIM model using the acquired BIM part. In addition, the operator terminal 2 instructs the design support system 10 to create drawings (construction drawing and fabrication drawing) of the BIM part included in the BIM model. The operator terminal 2 is provided to be operated by an operator (or a first user). The operator is, for example, a subcontractor who is commissioned by a constructor (or a second user) responsible for contracting the construction object, to create a construction drawing(s) and a fabrication drawing(s) of the construction object. A dedicated application (or software) for representing (or displaying) and editing the BIM model is installed in the operator terminal 2.

The constructor terminal 3 is provided as a terminal to be operated by a constructor. The constructor terminal 3 includes at least a function of representing the construction drawing which is created by the operator, a function of enabling an input of a comment with regard to the construction drawing, and a function of performing an approval operation with regard to the construction drawing.

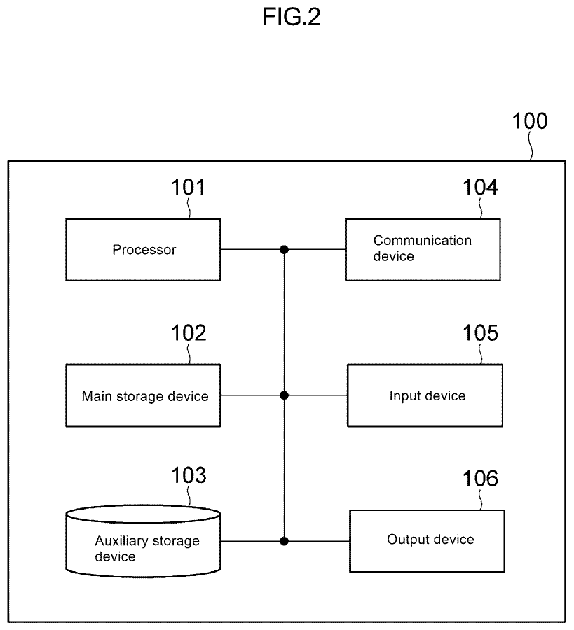

FIG. 2 depicts an example showing a hardware configuration of a computer 100 configuring the design support system 10 illustrated in FIG. 1. As depicted in FIG. 2, the computer 100 includes a processor 101, a main storage device 102, an auxiliary storage device 103, a communication device 104, an input device 105, and an output device 106. As the example of the processor 101, a CPU (Central Processing Unit) may be listed. The main storage device 102 is configured to include a RAM (Random Access Memory) and a ROM (Read Only Memory), etc. As the examples of the auxiliary storage device 103, a semiconductor memory and a hard disk device may be listed. As the examples of the communication device 104, a network card and a wireless communication module may be listed. As the examples of the input device 105, a keyboard and a mouse may be listed. As the example of the output device 106, a display may be listed. The operator terminal 2 and the constructor terminal 3 may also be configured by a computer similar to the above-mentioned computer 100.

As illustrated in FIG. 1, the design support system 10 is configured to include, as its functional components, a part providing unit 11, a parameter acquiring unit 12, a parameter changing unit 13, a construction drawing creating unit (or drawing creating unit) 14, a drawing presenting unit (or drawing displaying unit) 15, an approval processing unit 16, a fabrication drawing creating unit (or drawing creating unit) 17, and a storage unit (or memory) 18.

The part providing unit 11 provides a BIM part(s) relating to equipment (or facility) of a construction object in such a manner that the BIM part is capable of being incorporated into a BIM model. In the present embodiment, it is exemplified that the construction object is an interior part of a building, and the equipment of the construction object is a steel door fitting (or SD fitting). However, the combination of the construction object and the equipment is not limited to the above-mentioned example. In addition, the manner in which the BIM part is provided to be capable of being incorporated into the BIM model is not limited to the particular embodiment. For example, the part providing unit 11 may cause the operator terminal 2 to download a BIM part(s), or may provide a BIM part to a user in such a manner that the BIM part is capable of being used (or selected) on a platform running on a web which is provided by the design support system 10. In the present embodiment, the former case will be mainly described.

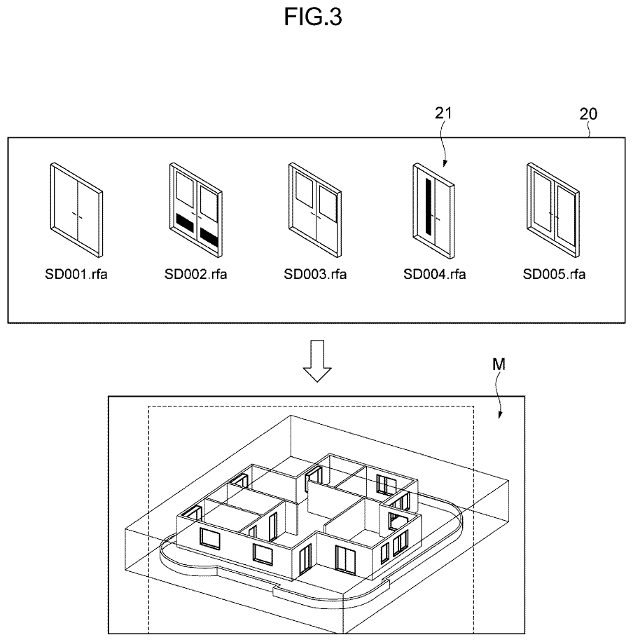

FIG. 3 depicts an example showing BIM parts and a BIM model. As illustrated in FIG. 3, according to the present embodiment, the part providing unit 11 provides the operator terminal 2 with a BIM part library 20 including a plurality of BIM parts 21 relating to the SD fitting. Each BIM part 21 is provided as digital data which is capable of being incorporated into the BIM model. In the present embodiment, as one example, each BIM parts 21 is configured as a file (or RFA file) in a format that is capable of being imported into the Autodesk Revit (registered trademark) which corresponds to the BIM software.

In the example illustrated in FIG. 3, it is exemplified that the BIM part library 20 includes five BIM parts 21. However, the type and the number of the BIM parts 21 included in the BIM part library 20 are not limited to the above-mentioned example. The BIM part library 20 may include a plurality of BIM parts 21 of standard specifications prepared in advance for each type, such as, the single swinging door, the double swinging door, the master and slave door, the single sliding door, the sliding door, the double sliding door, the drop door, and the automated door, etc. The five BIM parts 21 illustrated in FIG. 3 exemplify the BIM parts prepared for the double swinging door.

In FIG. 3, the BIM model M is illustrated as a BIM model which is created using the BIM parts 21 provided by the part providing unit 11. For example, an operator operates a dedicated application (in the present embodiment, a BIM software which is capable of importing RFA files) that had been installed in the operator terminal 2, and then, the BIM model M is created and represented (or displayed) on the operator terminal 2. That is, the operator downloads required BIM parts 21 (or the BIM part library 20 including a set of all BIM parts 21) from the part providing unit 11, imports the downloaded BIM parts 21 into the dedicated application, and places (any one or more of the BIM parts 21) in the BIM model M. As a result, the BIM model M in which the BIM parts 21 are incorporated is created.

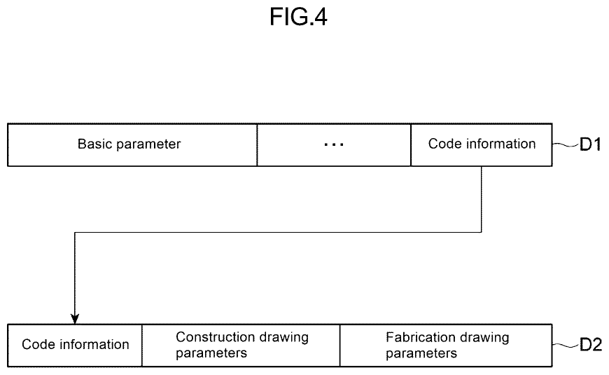

The respective BIM parts 21 have a data structure D1 as illustrated in FIG. 4. That is, each BIM part 21 is configured to include basic parameters and code information.

The basic parameters are provided for representing (or displaying) a three-dimensional shape of the BIM part 21. For example, the basic parameters include rendering data for three-dimensionally representing the BIM part 21 on the BIM model M. In addition, the basic parameters are capable of including the shape, the dimensions, the materials, the specifications, etc., of the SD fitting (in other words, data corresponding to the table of the fitting). In this way, the basic parameters are provided as data for indicating the basic information of the SD fitting corresponding to the BIM part 21.

The code information corresponds to a code (or identification information) which is uniquely assigned to the BIM part 21. For example, in a case where the BIM part 21 is provided as the above-mentioned RFA file, and a unique file name is assigned to each file (for example, “SD001.rfa” or the like as illustrated in FIG. 3), the file name of the BIM part 21 (for example, “SD001” or the like excluding the extension part from the file name) may be used as the code information. However, the code information is not limited to the filename, and arbitrary information which is capable of uniquely identifying the BIM part 21 may be used as the code information.

The storage unit 18 stores an additional parameter(s) for creating one or a plurality of drawings relating to constructing or manufacturing of the BIM part 21, in association with the code information of the BIM part 21. In the present embodiment, the storage unit 18 stores data having a data structure D2 illustrated in FIG. 4 for each BIM part 21. The data structure D2 is provided to have a data structure in which construction drawing parameters (or parameters relating to construction drawing) and fabrication drawing parameters (or parameters relating to fabrication drawing) each corresponding to the additional parameters are associated with the code information.

The construction drawing parameters correspond to parameters necessary for creating a construction drawing of the BIM part 21. The fabrication drawing parameters correspond to parameters necessary for creating a fabrication drawing (which may be a component drawing) of the BIM part 21 in addition to the construction drawing parameter. In other words, the fabrication drawing parameters (which may be component drawing parameters) are provided for supplementing necessary information which is insufficient in the construction drawing parameters only, for creating a fabrication drawing. The fabrication drawing contains information for indicating construction procedures of the BIM part 21 (or the SD fittings) in detail (for example, procedures for bending processes of a metallic plate or the like). On the other hand, the construction drawing corresponds to a drawing of a previous stage of the fabrication drawing (or corresponds to a drawing without including information for indicating detailed manufacturing procedures, different from the fabrication drawing), and is mainly used for a constructor (or construction worker) to confirm the content of the design subject.

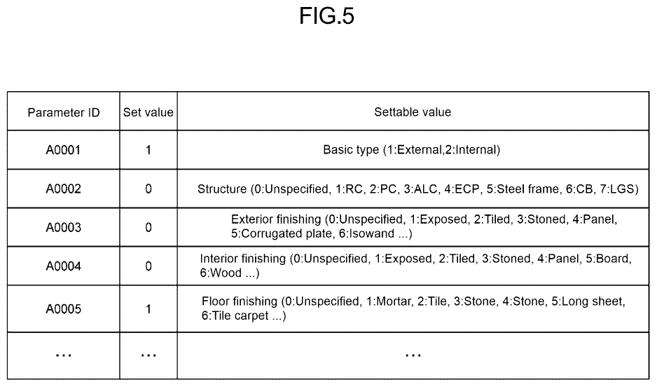

FIG. 5 depicts an example showing construction drawing parameters. According to the example of FIG. 5, each construction drawing parameter includes a parameter ID that is an identifier for specifying a parameter, and a setting value associated with the parameter ID. For each parameter, a settable value (or allowable value) is defined. The construction drawing parameters illustrated in FIG. 5 indicate that the basic type is “external (1)”, the structure is “unspecified (0)”, the exterior finishing is “unspecified (0)”, the interior finishing is “unspecified (0)”, and the floor finishing is “mortar (1)”. However, the parameters illustrated in FIG. 5 are parts of the parameters included in the construction drawing parameters, and the construction drawing parameters include, in addition to the parameters illustrated in FIG. 5, information for specifying various configurations necessary for creating a construction drawing of the BIM part 21.

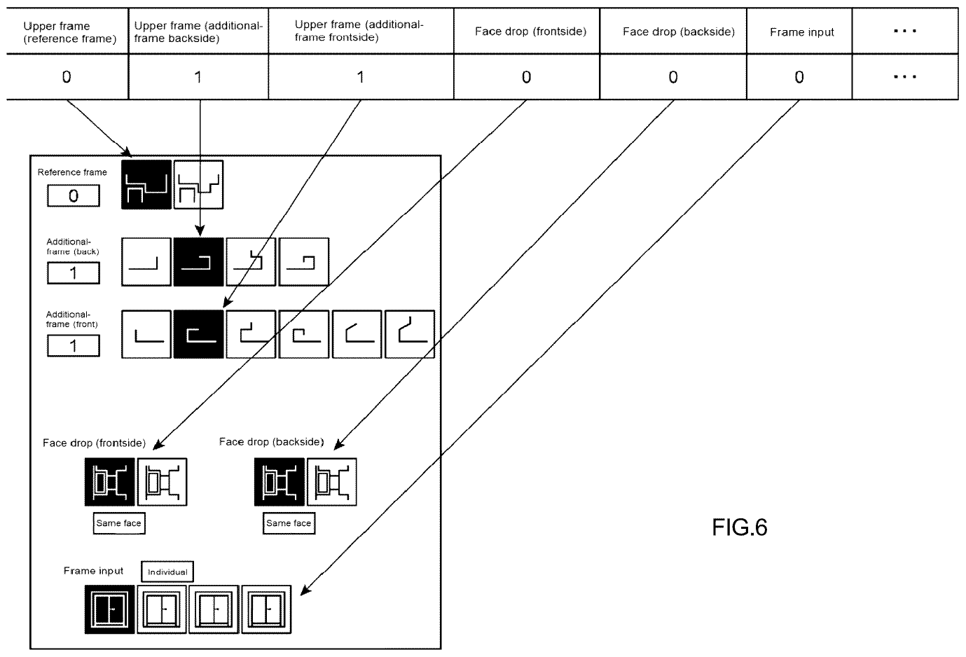

FIG. 6 depicts an example showing fabrication drawing parameters. The fabrication drawing parameters illustrated in FIG. 6 indicate that the form of the upper frame (or reference frame) is the form corresponding to “0” which is registered in advance; the form of the upper frame (additional-frame backside) is the form corresponding to “1” which is registered in advance; the form of the upper frame (additional-frame frontside) is the form corresponding to “1” which is registered in advance; the form of the face drop (frontside) is the from corresponding to “0” which is registered in advance; the form of the face drop (backside) is the form corresponding to “0” which is registered in advance; and the form of the door frame (frame input) is the form corresponding to “0” which is registered in advance. In this case, the parameters illustrated in FIG. 6 are parts of the parameters relating to the frame shape of the BIM part 21 among the fabrication drawing parameters of the BIM part 21 (or SD fitting), and the fabrication drawing parameters include information for specifying various configurations necessary for creating a fabrication drawing of the BIM part 21 in addition to the parameters illustrated in FIG. 6. As the examples of the fabrication drawing parameters, other than the parameters illustrated in FIG. 6, product information of the hardware used in the BIM part 21, information for indicating the attachment position and the like, information for indicating the bending position, the bending direction and the like of the bending may be listed.

The parameter acquiring unit 12 acquires code information of the BIM part 21 included in the BIM model, and then, acquires additional parameters in association with the acquired code information from the storage unit 18. For example, the parameter acquiring unit 12 acquires code information of the BIM part 21 designated by the operator among the BIM parts 21 included in the BIM model M which is created by the operator by operating the operator terminal 2. Subsequently, the parameter acquiring unit 12 acquires additional parameters (or construction drawing parameters or fabrication drawing parameters) corresponding to the acquired code information.

The parameter changing unit 13 executes a changing process of at least a part of the additional parameters acquired by the parameter acquiring unit 12 based on the operation content inputted by the operator. For example, the parameter changing unit 13 generates a setting screen (or configuration screen) for editing setting values of the construction drawing parameters as illustrated in FIG. 5 or setting values of the fabrication drawing parameters as illustrated in FIG. 6, and displays the setting screen on the operator terminal 2. It is possible to display default values (in other words, values set in the construction drawing parameters or the fabrication drawing parameters, each associated with the BIM part 21) on the configuration screen. The operator is able to change any one or more of the default values to another setting value(s) by performing the input operation on the configuration screen. That is, the parameter changing unit 13 receives the changing operation of the default values of the additional parameters (or the construction drawing parameters or the fabrication drawing parameters) to different setting values. The information of the additional parameters that has been changed by the above-mentioned operation is stored in the storage unit 18 separately from the previously stored information of the additional parameters.

The construction drawing creating unit 14 creates a construction drawing or figure of the BIM part 21 based on the construction drawing parameters acquired by the parameter acquiring unit 12. For example, the construction drawing creating unit 14 is provided with a construction-drawing-creating program for creating a construction drawing having a predetermined format, based on the construction drawing parameters. In this case, when the construction drawing parameters acquired by the parameter acquiring unit 12 are inputted into the construction-drawing-creating program, the construction drawing creating unit 14 is able to automatically create a construction drawing according to the construction drawing parameters.

In a case where at least a part of the construction drawing parameters is changed by the above-mentioned parameter changing unit 13, the construction drawing creating unit 14 creates a construction drawing of the BIM part 21 based on the construction drawing parameters that have been changed by the parameter changing unit 13.

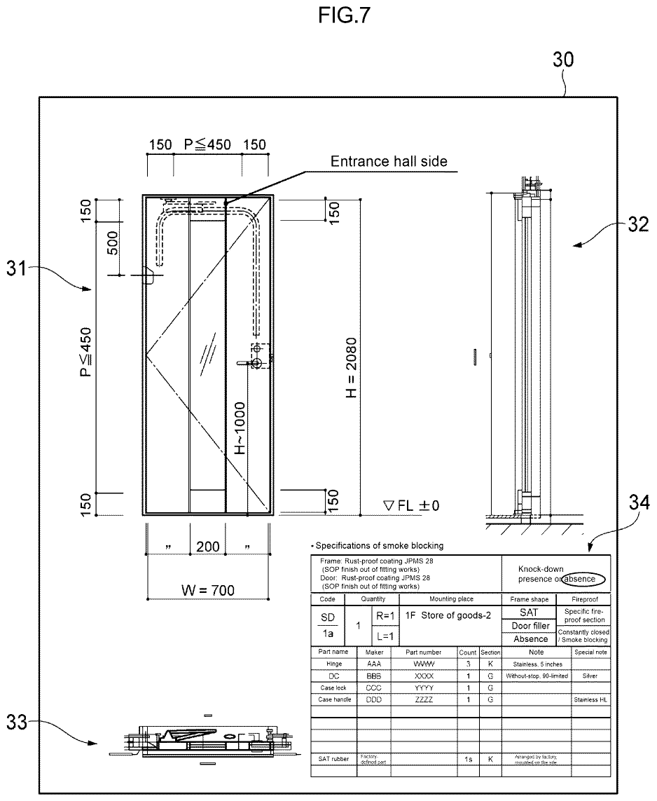

FIG. 7 depicts an example showing a construction drawing. As illustrated in FIG. 7, as an example, a construction drawing 30 may include a front view 31, a side sectional view 32, and a plan view 33 of a BIM part 21, and also text information 34 (for example, information represented in a table format) indicating detailed information such as the frame shape, the components, and the finishing of the BIM part 21.

The drawing presenting unit 15 presents a construction drawing (see FIG. 7) created by the construction drawing creating unit 14 to a constructor. For example, the drawing presenting unit 15 transmits displaying information of the construction drawing to the constructor terminal 3. Accordingly, the constructor is able to confirm the construction drawing which is displayed on the display of the constructor terminal 3.

The approval processing unit 16 receives an approval operation with regard to the construction drawing by the constructor. For example, when the constructor operates the constructor terminal 3, the approval processing unit 16 receives the information indicating the approval operation inputted from the constructor terminal 3, thereby receiving the approval operation.

If the contractor is not satisfied with the content of the construction drawing and wishes to perform a correction operation (or changing operation) with regard to the construction drawing, the contractor is able to reject the construction drawing without approving it. In such a case, the operator is able to change (or correct) the content of the construction drawing which is created by the construction drawing creating unit 14 by modifying the BIM model M, or by changing the construction drawing parameters by performing the above-mentioned operation with regard to the parameter changing unit 13. Subsequently, the modified construction drawing is presented to the constructor (or the constructor terminal 3) by the drawing presenting unit 15. In order to facilitate such the exchange process between the operator and the constructor, the approval processing unit 16 may be provided with the following functions.

That is, the approval processing unit 16 is capable of receiving an input of a comment with regard to the construction drawing by the operator or the constructor, and of associating the comment with the construction drawing when the comment is inputted so that the comment is able to be presented to both the operator and the constructor. For example, the approval processing unit 16 acquires a comment inputted by the operator via the operator terminal 2 or a comment inputted by the constructor via the constructor terminal 3. The comment may be arranged by specifying an arbitrary place on the construction drawing (see FIG. 7). That is, the approval processing unit 16 is capable of providing the operator terminal 2 and the constructor terminal 3 with an interface for inserting a comment by specifying an arbitrary place on the construction drawing. For example, the approval processing unit 16 may display a construction drawing and also generate screen information which is configured to be capable of inputting a comment as described above with regard to the construction drawing, and transmit the screen information to the operator terminal 2 and the constructor terminal 3. Subsequently, the approval processing unit 16 may receive a comment (transmitted from the operator terminal 2 or the constructor terminal 3) which is inputted to the screen information on the operator terminal 2 or the constructor terminal 3, and also re-transmit the screen information reflecting the comment to the operator terminal 2 and the constructor terminal 3. According to such a system, it is possible to promote a communication between the operator and the constructor, via the interface (or screen information) provided by the design support system 10 (or the approval processing unit 16).

The fabrication drawing creating unit 17 creates a fabrication drawing or figure of the BIM part 21 based on the fabrication drawing parameters acquired by the parameter acquiring unit 12. When creating a fabrication drawing, it is possible to use any ones of the construction drawing parameters which are necessary for creating the fabrication drawing, in combination with the fabrication drawing parameters. For instance, the fabrication drawing creating unit 17 is provided with a fabrication drawing-creating program for creating a fabrication drawing of a predetermined format based on the fabrication drawing parameters (in combination with the necessary construction drawing parameters; the same applies hereafter). In this case, the fabrication drawing creating unit 17 is capable of automatically creating a fabrication drawing according to the fabrication drawing parameters, by inputting the fabrication drawing parameters acquired by the parameter acquiring unit 12 into the fabrication drawing-creating program.

In a case where at least a part of the fabrication drawing parameters is changed by the above-mentioned parameter changing unit 13, the fabrication drawing creating unit 17 creates a fabrication drawing of the BIM part 21 based on the fabrication drawing parameters that have been changed by the parameter changing unit 13.

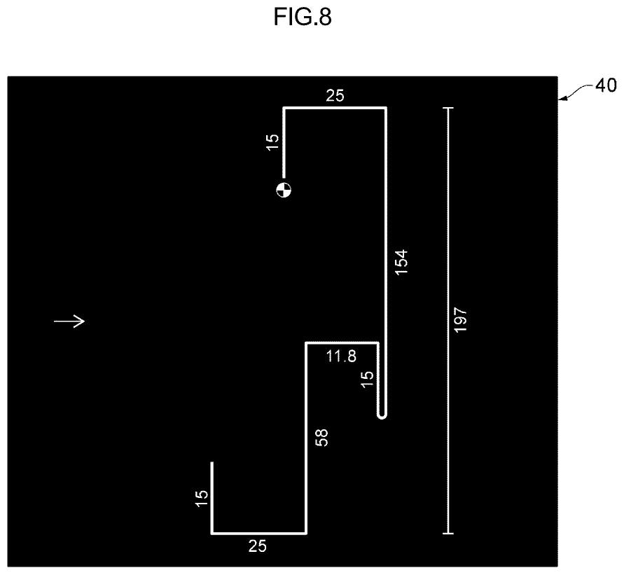

FIG. 8 depicts an example showing a fabrication drawing. The fabrication drawing 40 illustrated in FIG. 8 depicts one example of the fabrication drawing including information (for example, the bending shape, the bending dimension, etc.) necessary for bending of the main body portion (or portion formed by a metal plate) of the BIM part 21 as the SD fitting.

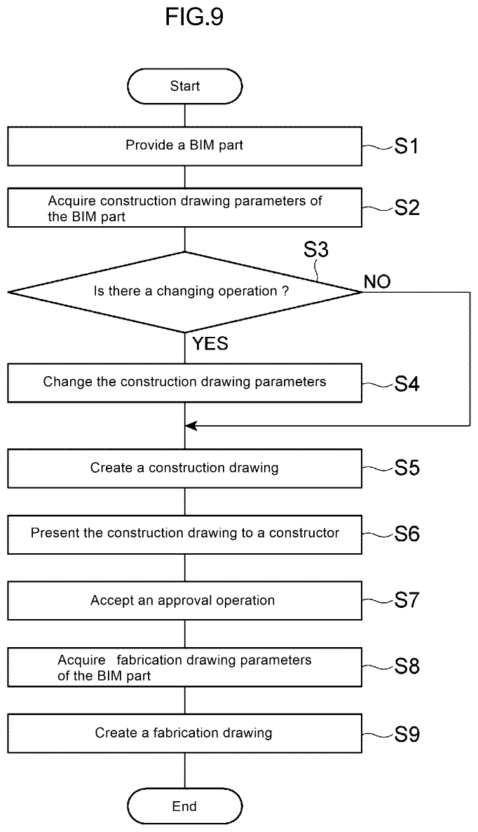

Next, an example of the operations of the design support system 10 (including the design support method according to one embodiment) will be described with referring to FIG. 9.

At the step S1, the part providing unit 11 provides a BIM part(s) 21 (see FIG. 3) to an operator (or operator terminal 2) in such a manner that the BIM part 21 is capable of being incorporated into a BIM model M (see FIG. 3). Accordingly, the operator is able to create the BIM model M using the BIM part 21 by operating the operator terminal 2.

At the step S2, the parameter acquiring unit 12 acquires code information of the BIM part 21 that is included in the BIM model created by the operator operating the operator terminal 2, and also acquires the construction drawing parameters (see FIG. 5) in association with the acquired code information from the storage unit 18.

In a case where the operator performs the changing operation of the construction drawing parameters via the operator terminal 2 (step S3: YES), the parameter changing unit 13 executes a changing process for changing at least a part of the construction drawing parameters which are acquired by the parameter acquiring unit 12, according to the operation content inputted by the operator (step S4). On the other hand, in a case where the changing operation of the construction drawing parameters is not performed (step S3: NO), the process of the step S4 is skipped.

At the step S5, the construction drawing creating unit 14 creates a construction drawing (see FIG. 7) of the BIM part 21 based on the construction drawing parameters acquired by the parameter acquiring unit 12. In a case where at least a part of the construction drawing parameters is changed at the step S4, the construction drawing creating unit 14 creates a construction drawing of the BIM part 21 based on the construction drawing parameters that have been changed.

At the step S6, the drawing presenting unit 15 presents the construction drawing which is created by the construction drawing creating unit 14, to a constructor.

At the step S7, the approval processing unit 16 accepts an approval operation with regard to the construction drawing, inputted by the constructor. By using the above-mentioned input of a comment by the approval processing unit 16 and a sharing function thereof, comments may be exchanged between the operator and the constructor as necessary. In addition, if correction of the construction drawing is required (in other words, correction of the construction drawing parameters is required), the process of the step S4 may be executed again.

At the step 8, the parameter acquiring unit 12 acquires fabrication drawing parameters (see FIG. 6) in association with the code information of the BIM part 21 which is acquired at the step S2, from the storage unit 18.

At the step S9, the fabrication drawing creating unit 17 creates a fabrication drawing (see FIG. 8) of the BIM part 21 based on the fabrication drawing parameters acquired by the parameter acquiring unit 12. Similar to the case of the construction drawing parameters, at least a part of the fabrication drawing parameters may be changed by the parameter changing unit 13. In this case, the fabrication drawing creating unit 17 creates a fabrication drawing of the BIM part 21 based on the fabrication drawing parameters that have been changed. By the above way, the series of processes of the design support system 10 is completed.

According to the above-mentioned design support system 10 and the design support method (FIG. 9), the code information is embedded in the BIM part 21 itself, instead of embedding information (or additional parameters) for creating a drawing (in the present embodiment, the construction drawing or the fabrication drawing). The additional parameters contain a great deal of information. Therefore, by storing such information in the storage unit 18 external to the BIM part 21 instead of in the BIM part 21, it becomes possible to suppress an increase in the data volume of the individual BIM part 21. Consequently, it is possible to suppress an increase in the data volume of the BIM model M. In addition, the above-mentioned design support system 10 and the design support method are configured such that the parameter acquiring unit 12 acquires additional parameters in association with the code information embedded in the BIM part 21, and the drawing creating unit (or the construction drawing creating unit 14 or the fabrication drawing creating unit 17) creates a drawing (or the construction drawing or the fabrication drawing) according to the additional parameters. With such a configuration, the drawing creation process of the BIM part 21 is capable of being automated and facilitated so that it is possible to effectively improve the convenience of the user (mainly, the operator).

Further, the additional parameters may correspond to confidential information including know-how or the like designed by an administrator of the design support system 10 (or, by a provider of service using the design support system 10) over a large amount of time. Therefore, by storing such confidential information on the outside of the BIM part 21, and by making it accessible only from the design support system 10, it becomes possible to improve the confidentiality of the confidential information relating to the BIM part 21 and to prevent the leakage (or outflow) of the confidential information.

Further, the design support system 10 is provided with the parameter changing unit 13 so that the drawing creation unit (or the construction drawing creating unit 14 or the fabrication drawing creating unit 17) is capable of creating a drawing (or the construction drawing or the fabrication drawing) of the BIM part 21 based on the additional parameters that have been changed by the parameter changing unit 13. According to the above-mentioned configuration, the operator is able to freely customize additional parameters which are previously related to the BIM part 21. As a result, the content of the drawing relating to the BIM part 21 is able to be flexibly adjusted so that it is possible to further improve the convenience of the user (mainly, the operator).

In addition, the design support system 10 is provided with the drawing presenting unit 15 and the approval processing unit 16. According to the above-mentioned configuration, it is possible to smoothly proceed the process of presenting the created drawing (in the present embodiment, the construction drawing) to the constructor, and the process of accepting an approval operation of the constructor with regard to the drawing. Accordingly, it is possible to further improve the convenience of the user (both the operator and the constructor).

In addition, the approval processing unit 16 is capable of receiving an input of a comment with regard to the drawing (in the present embodiment, the construction drawing) by the operator or the constructor, and associating the comment with the drawing when the comment is inputted, so that the comment is presented to both the operator or the constructor. According to the above-mentioned configuration, it is possible to share the content of the inputted comment between the operator and the constructor while enabling the input operation of the comment by the operator or the constructor with regard to the drawing. As a result, it is possible to promote a communication between the operator and the constructor, and thereby to smooth the flow until the drawing is approved by the constructor. Accordingly, it is possible to further improve the convenience of the user (both the operator and the constructor).

Further, according to the design support system 10, the construction drawing and the fabrication drawing are created in stages as follows. That is, at first, after the construction drawing creating unit 14 creates the construction drawing based on the construction drawing parameters, the drawing presenting unit 15 presents the construction drawing to the constructor (or the constructor terminal 3). Subsequently, the approval processing unit 16 accepts the approval operation with regard to the construction drawing by the constructor. Subsequently, after the approval operation with regard to the construction drawing is received by the approval processing unit 16 (that is, after the content of the construction drawing is confirmed), the fabrication drawing creating unit 17 creates the fabrication drawing based on the fabrication drawing parameters. According to the above-mentioned configuration, it is possible to smoothen the flows of the creation and the approval of the construction drawing as well as of the creation of the fabrication drawing after the construction drawing has been approved. Accordingly, it is possible to further improve the convenience of the user (both the operator and the constructor).

The design support system and the design support method according to the present disclosure are not limited to the above-mentioned embodiments. Some of the functions included in the design support system 10 of the above-mentioned embodiments may be omitted or replaced with other functions. For example, in a case where it is not necessary to obtain the approval from the constructor with regard to the construction drawing (in other words, in a case where only the fabrication drawing for proceeding to manufacturing process of the fitting is required to be created), the construction drawing creating unit 14, the drawing presenting unit 15, and the approval processing unit 16 may be omitted.

Also, in the above-mentioned embodiment, as one example of the drawing creating unit provided in the design support system, the construction drawing creating unit 14 for creating the construction drawing as well as the fabrication drawing creating unit 17 for creating the fabrication drawing are exemplified. However, the type of the drawings created by the drawing creation unit are not limited to the construction drawing and the fabrication drawing. The design support system may be configured to create a drawing other than the construction drawing and the fabrication drawing by using a system similar to that of the above-mentioned embodiments. In such a case, the code information embedded in the BIM part 21 and parameters necessary for creating an arbitrary drawing relating to the BIM part 21 may be correlated to each other and stored in the storage unit 18.

Also, in the above-mentioned embodiments, the processes of creating (or editing) the BIM model M and of representing it are executed by the operator terminal 2 (in other words, by a dedicated application which is installed in the operator terminal 2). However, the design support system 10 may execute the processes of the creation and the representation of the BIM model M based on the user operations via the operator terminal 2. In other words, the design support system 10 may be provided with a BIM software for creating (or editing) the BIM model M and representing it.

In addition, according to the above-mentioned embodiment, the operator is exemplified as the first user and the constructor is exemplified as the second user. However, the combination of the first user and the second user is not limited to the combination of the operator and the constructor. For example, at the step of the designing the BIM model M of the construction object, a designer or the like belonging to a design office or a construction company may use the design support system 10 (mainly the BIM parts provided by the part providing unit 11) as the first user.

### REFERENCE SIGNS LIST

10 . . . Design support system,
11 . . . Part providing unit,
12 . . . Parameter acquiring unit,
13 . . . Parameter changing unit,
14 . . . Construction drawing creating unit (or Drawing creating unit),
15 . . . Drawing presenting unit (or Drawing displaying unit),
16 . . . Approval processing unit,
17 . . . Fabrication drawing creating unit (or Drawing creating unit),
18 . . . Storage unit (or Memory),
21 . . . BIM part,
30 . . . Construction drawing,
40 . . . Fabrication drawing (or Component drawing),
M . . . BIM model

1. A design support system comprising:
a part providing unit for providing a BIM part relating to equipment of a construction object in such a manner that the BIM part is capable of being incorporated into a BIM model, wherein the BIM part includes a basic parameter for representing a three-dimensional shape of the BIM part in the BIM model of the construction object and includes code information that is uniquely assigned to the BIM part;
a storage unit for storing an additional parameter for creating a drawing regarding construction or manufacturing of the BIM part, in association with the code information of the BIM part;
a parameter acquiring unit for acquiring the code information of the BIM part that is included in the BIM model created by a first user, and for acquiring the additional parameter in association with the acquired code information from the storage unit; and
a drawing creating unit for creating the drawing of the BIM part based on the additional parameter acquired by the parameter acquiring unit.

2. The design support system according to claim 1, further comprising a parameter changing unit for executing, based on an operation content inputted by the first user, a changing process for changing at least a part of the additional parameter acquired by the parameter acquiring unit;
wherein the drawing creating unit creates the drawing of the BIM part based on the additional parameter that has been changed by the parameter changing unit.

3. The design support system according to claim 1, further comprising:
a drawing presenting unit for presenting the drawing created by the drawing creating unit to a second user different from the first user; and
an approval processing unit for receiving an approval operation with regard to the drawing by the second user.

4. The design support system according to claim 3, wherein the approval processing unit receives an input of a comment with regard to the drawing by the first user or the second user, and
wherein the approval processing unit associates the comment with the drawing in a case where the comment is inputted, whereby the comment is represented to both the first user and the second user.

5. The design support system according to claim 3, wherein the additional parameter includes a construction drawing parameter necessary for creating a construction drawing of the BIM part, and includes a fabrication drawing parameter necessary for creating a fabrication drawing of the BIM part in addition to the construction drawing parameter,
wherein the drawing creating unit includes a construction drawing creating unit for creating a construction drawing of the BIM part according to the construction drawing parameter, and includes a fabrication drawing creating unit for creating a fabrication drawing according to the fabrication drawing parameter,
wherein the drawing presenting unit presents the construction drawing created by the construction drawing creating unit to the second user,
wherein the approval processing unit receives the approval operation with regard to the construction drawing, by the second user, and
wherein the fabrication drawing creating unit creates the fabrication drawing based on the fabrication drawing parameter after the approval operation with regard to the construction drawing is received by the approval processing unit.

6. A method of supporting a design for a construction object comprising:
providing a BIM part relating to equipment of a construction object in such a manner that the BIM part is capable of being incorporated into a BIM model, wherein the BIM part includes a basic parameter for representing a three-dimensional shape of the BIM part in the BIM model of the construction object and includes code information that is uniquely assigned to the BIM part;
acquiring the code information of the BIM part that is included in the BIM model created by a first user, and for acquiring an additional parameter in association with the acquired code information by accessing a storage unit that stores the additional parameter for creating a drawing regarding construction or manufacturing of the BIM part, in association with the code information of the BIM part; and
creating the drawing of the BIM part based on the acquired additional parameter.
